(19) United States
(12) Patent Application Publication
(10) Pub. No.: US 2015/0177321 A1
(43) Pub. Date: Jun. 25, 2015

(54) DEVICE FOR TESTING AND MONITORING DIGITAL CIRCUITS

(71) Applicant: Commissariat A L'ENERGIE ATOMIQUE ET AUX ENERGIES ALTERNATIVES, Paris (FR)

(72) Inventor: Valentin Gherman, Palaiseau (FR)

(21) Appl. No.: 14/403,127

(22) PCT Filed: Mar. 15, 2013
(86) PCT No.: PCT/EP2013/055336

§ 371 Date: Nov. 21, 2014

(30) Foreign Application Priority Data
May 21, 2012 (FR) 1254611

(51) Int. Cl. G01R 31/3177; G01R 31/317

(52) U.S. Cl. CPC G01R 31/3177; G01R 31/31725; G01R 31/31703

(57) ABSTRACT

A device for testing and monitoring digital circuits for detecting timing faults affecting a signal D received directly at the input of a flip-flop called primary sampling element, supplying a first value D₁ of the signal D and receiving a first clock signal, including at least: a scan logic module having a first input receiving the signal “D”, a second input receiving a “scan in” signal and a third input receiving a “scan enable” signal suitable for selecting the operating mode of the testing device in a scan mode or an operational mode, and an output linked to a secondary sampling element supplying a second sampled signal D₂ of the signal D after passing through the scan logic module, and receiving a second clock signal; a module for comparison of the signal D₁ and the signal D₂ generating an alert or error signal.

The subject of the invention relates to a device for testing and monitoring sequential digital circuits, the device being inserted, for example, into an observation and control chain or “scan chain”, with minimal impact on the latency of these circuits. The devices according to the invention make it possible to avoid the use of standard scan flip-flops, known to those skilled in the art, on critical paths.

The expression “critical path” in the present description denotes an electrical path between a flip-flop or a primary input and another flip-flop or a primary output which is distinguished by the fact that the latency of propagation of the electrical signals that travel along the path is one of the largest latencies characterizing the electrical paths of a circuit (between a flip-flop or a primary input and another flip-flop or a primary output).

Circuits based on micro- and nanotechnology can be affected by faults that are generated, for example, by physical faults resulting from the method of production or the aging process, by poor matching of the clock frequency of the circuit to the supply voltage, and/or by variations in the temperature or the supply voltage. These faults can generate operating errors and finally the failure of the systems in which these circuits are used.

Physical faults introduced into the circuits during the production process can be identified using production tests. The capacity to detect these faults can be significantly increased using test-oriented design solutions offering the possibility of configuring some or all of the flip-flops of the circuits in scan chains during the test. An example is given in pages 366-368 of the book by M. Abramovici, M. A. Breuer, A. D. Friedman “Digital Systems Testing and Testable Design”, IEEE Press, 1990.

Other sources of failure generally manifest as timing faults. One of the most effective approaches for preventing these failures is to detect any timing faults before they generate errors. Among the solutions of this type known to those skilled in the art, certain monitoring techniques provide on-line detection of timing faults by carrying out double sampling of the signals on critical paths.

One of these solutions relies on the use of a timing element, for example a “Buffer”, sampling elements at the input and the output of the timing element, and an element for comparing the outputs of the sampling elements. Examples of this method are described, for example, in the publication by S. Mitra, N. Siefert, M. Zhang, Q. Shi, K. S. Kim “Robust system design with built-in soft-error resilience,” IEEE Computer, Special Issue on Nano-Scale Design and Test, 38(2), pp. 43-52, 2005 or the publication by M. Nicolaidis “Time Redundancy Based Soft-Error Tolerance to Rescue Nanometer Technologies,” VLSI Test Symposium (VTS), 1999. In the following text, sampling elements at the input of the timing elements will be called primary sampling elements while sampling elements at the output of the timing elements will be called secondary sampling elements. The primary sampling elements are flip-flops used to make computations relating to the functionality of the circuit, whereas the secondary sampling elements are flip-flops used for comparing the signals at the input and the output of the timing elements. A difference between the two sampled values indicates a timing fault that has not yet manifested as an error and the value of which is less than the time margin normally introduced into clock periods to absorb variations in the latency of digital circuits. As soon as a timing fault is detected, an error or alert signal is generated.

One of the aims of the present invention is to supply a testing and monitoring device connected to flip-flops in a sequential circuit in order to:
reduce the impact on performance of the test-oriented solutions based on scan chains,
enable the on-line detection of timing faults based on time-shifted double sampling.

The device according to the invention can be incorporated into scan chains and makes it possible to avoid using standard scan flip-flops, known by those skilled in the art, on critical paths.

The subject of the present invention relates to a device for testing and monitoring digital circuits enabling the detection of timing faults affecting a signal D received directly at the input of a flip-flop called primary sampling element, said primary sampling element supplying a first value D₁ of the signal D and receiving a first clock signal for its updating, said testing and monitoring device comprising at least:
a scan logic module introducing a latency in the signal D, said scan logic module having a first input receiving the signal “D”, a second input receiving a “scan in” signal and a third input receiving a “scan enable” signal suitable for selecting the operating mode of the testing and monitoring device in a scan mode or an operational (functional) mode, and an output linked to a secondary sampling element of the signal “D” and supplying a second sampled signal D₂ of the signal “D” after passing through the scan logic module, said secondary sampling element receiving a second clock signal for updating its state,
a module for comparison of the signal D₁ and the signal D₂ generating an alert or error signal.

The module supplying a “reset” signal to the primary sampling element comprises, for example, two NAND gates suitable for generating a selective “reset” in scan mode and a normal “reset” in operational mode.

In a variant embodiment, the module supplying a “reset” signal to the primary sampling element comprises a NAND gate with a first input receiving a reset signal and a second input receiving the inverted output signal of the secondary sampling element “scan out”, and the primary sampling element is chosen so that its state is forced to the value logic 1 as soon as the “scan enable” signal takes the value logic 1.

The device can comprise a module supplying a “reset” signal (reset to zero) to said primary sampling element.

The device comprises, for example, a module suitable for generating a signal for controlling the holding of the state of said primary sampling element.

In a variant embodiment, the first clock signal and the second clock signal are identical.

Said secondary sampling element and the “scan logic” module form, for example, a standard flip-flop.

The device can comprise an XOR gate used to compare the versions of the signal “D” sampled by said primary sampling element and by said secondary sampling element.

The device comprises, for example, an inverter on the path of the second clock signal.

The device comprises, for example, a timing element arranged on the path of the first clock signal and/or arranged on the path of the second clock signal.

The “scan logic” module comprises, for example, a multiplexer controlled by the “scan enable” signal.

In another variant embodiment, the “scan logic” module comprises an XNOR gate, a NOR gate and a NAND gate or an XOR gate, a NOR gate and a NAND gate.

For a primary sampling element comprising an explicit input for a hold signal, the “hold logic” module is composed of a NAND gate whose “scan enable” and “hold” inputs are inverted.

In the case of a primary sampling element comprising an explicit input for a “hold” signal, the “hold logic” module is composed of two NAND gates whose “hold” input is inverted.

For a primary sampling element not including an explicit input for a “hold” signal, the “hold logic” module is composed of a NOR gate receiving the first clock signal and the “scan enable” signal as input.

For a primary sampling element not including an explicit input for a “hold” signal, the “hold logic” module is composed of a NOR gate and an AND gate, the NOR gate receives the first clock signal on a first input and the output of the AND gate on a second input.

For a primary sampling element not including an explicit input for a “hold” signal, the “hold logic” module contains a first NAND gate and a second NAND gate, the first NAND gate receives the first clock signal on a first input and the output of the second NAND gate on a second input.

For a primary sampling element not including an explicit input for a “hold” signal and which has a “reset” input synchronous with the first clock signal, the input corresponding to the “reset” signal in the “hold logic” module is blocked at the value logic 0.

At least some of the primary and/or secondary sampling elements are suitable for updating their state on the falling edge of their clock signal.

In a variant embodiment, at least some of the primary and/or secondary sampling elements are suitable for updating their state on the high or low level of their clock signal.

The invention also relates to the use of the device having one of the aforementioned features in a circuit that comprises several scan chains comprising one or more testing and monitoring devices, said testing and monitoring devices being arranged on critical paths of said system.

Alternatively, the invention relates to the use of the device having at least one of the aforementioned features in a circuit comprising several scan chains containing at least one testing and monitoring device according to the invention.

Other features and advantages of the device according to the invention will become better apparent upon reading the following description of an exemplary non-limiting embodiment given for the purposes of illustration, with the appended figures representing:

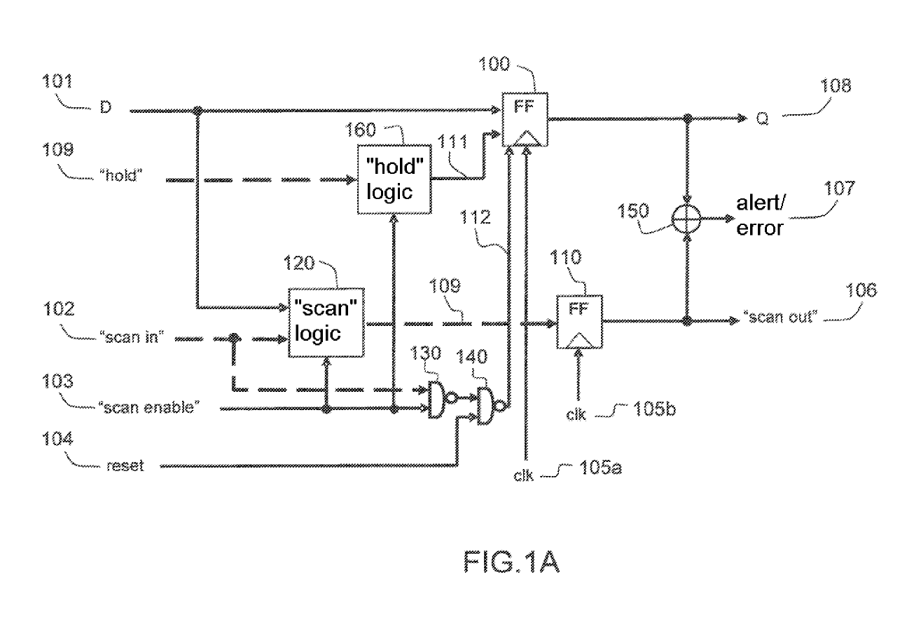

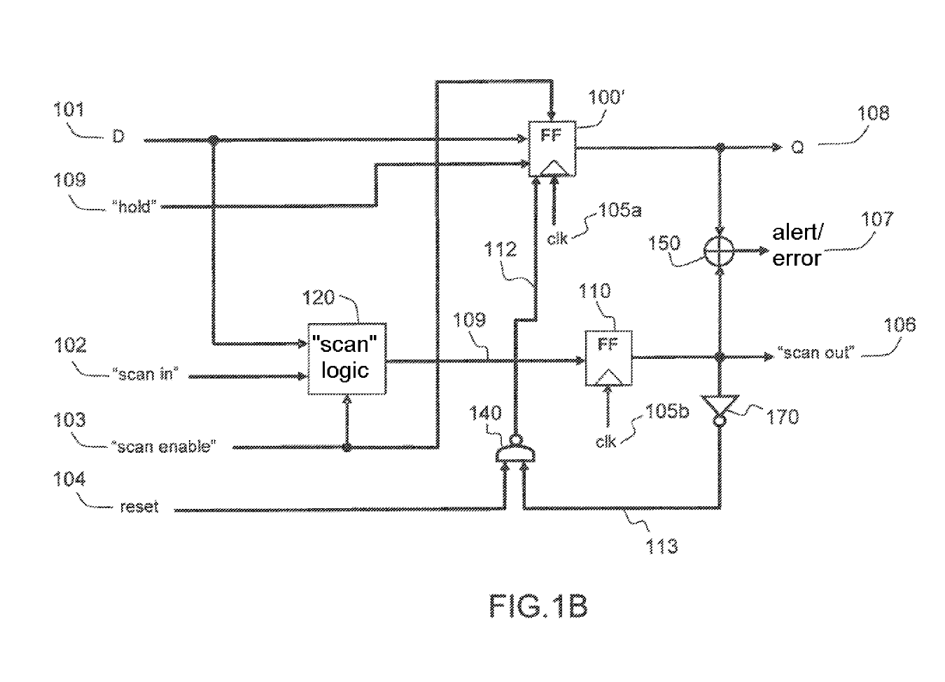

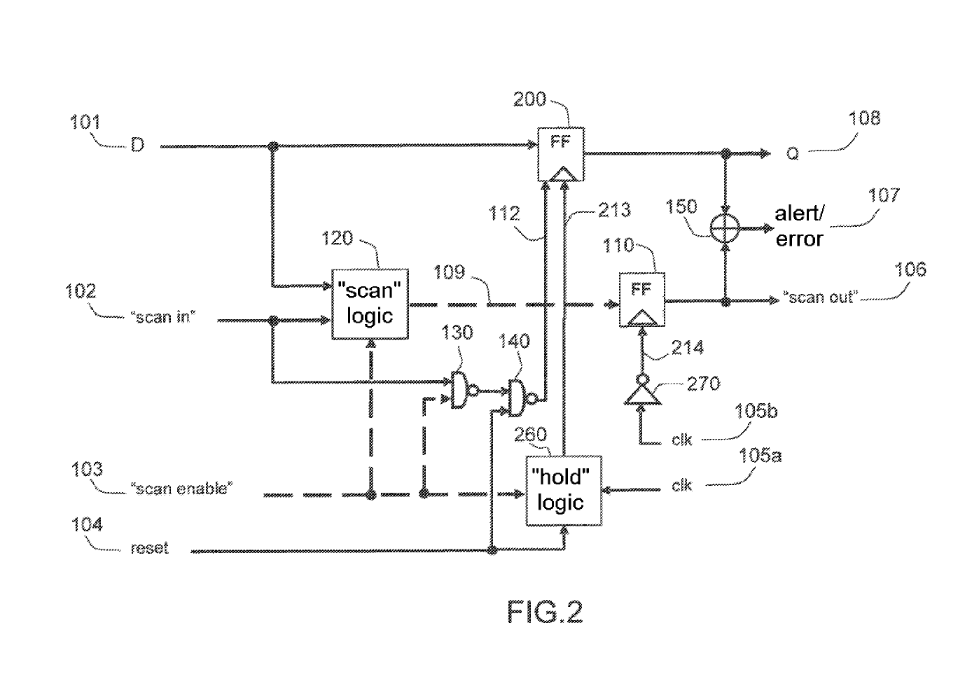

FIG. 1A, FIG. 1B and FIG. 2, an example of testing and monitoring devices according to the invention,

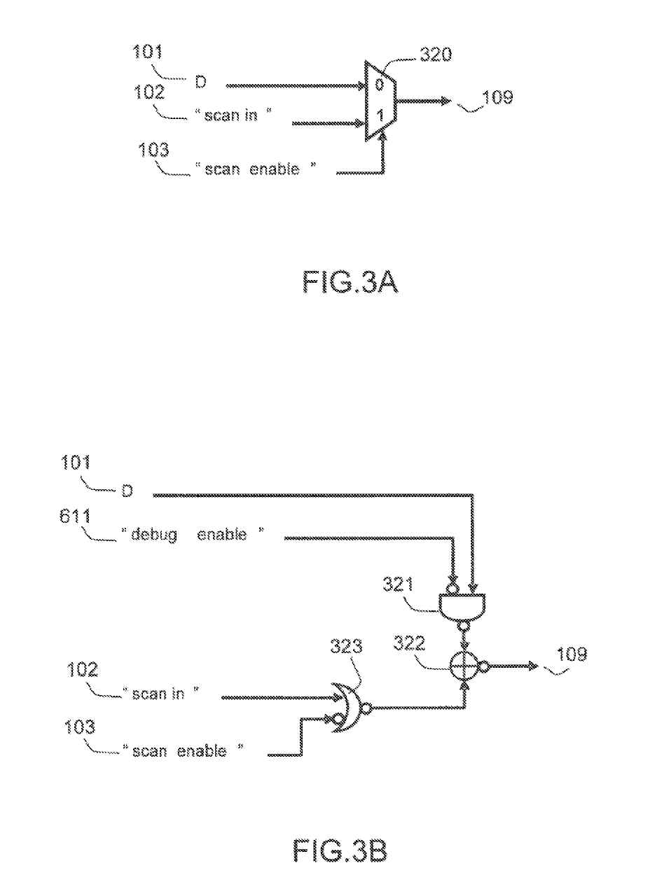

FIGS. 3A and 3B, two modes of implementation for the “scan logic” elements of FIGS. 1A and 2, respectively.

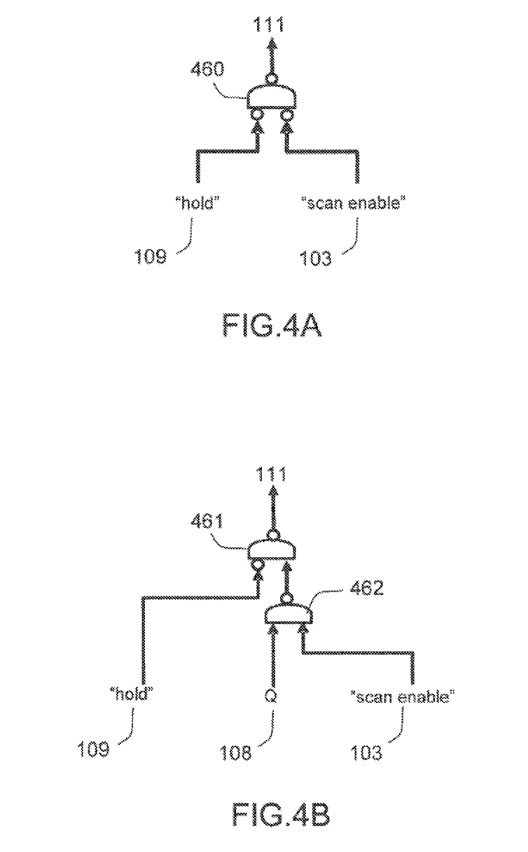

FIG. 4, two examples of modes of implementation for the “hold logic” element of FIG. 1A,

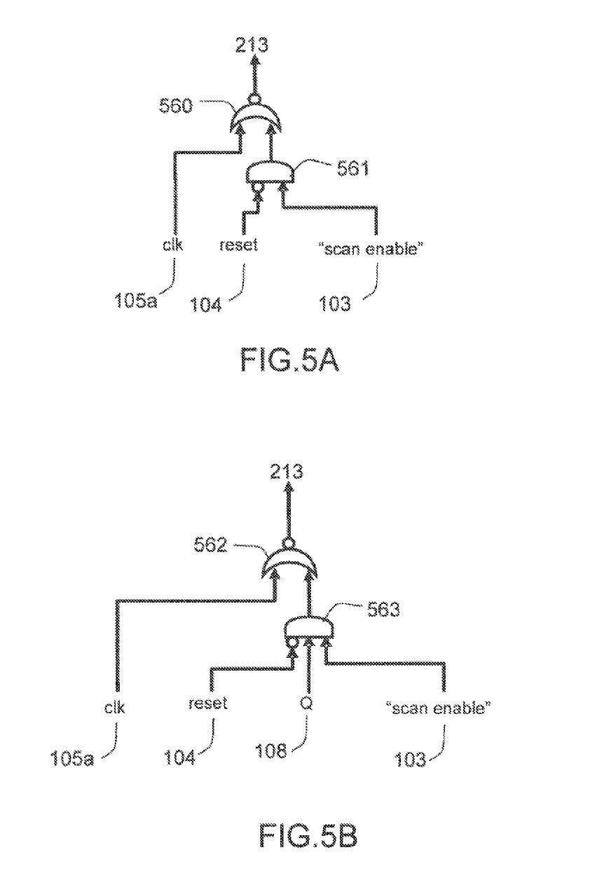

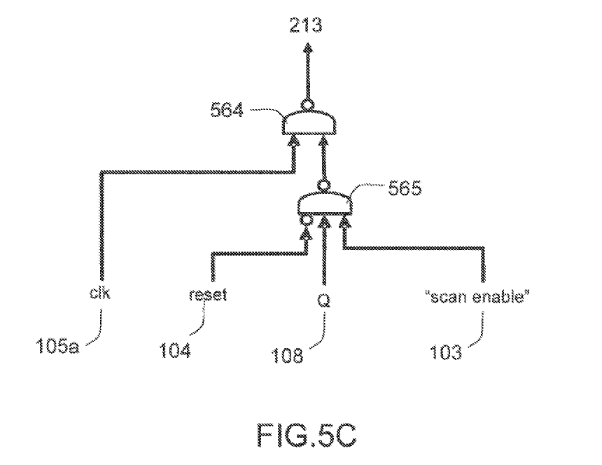

FIG. 5, three examples of modes of implementation for the “hold logic” element of FIG. 2,

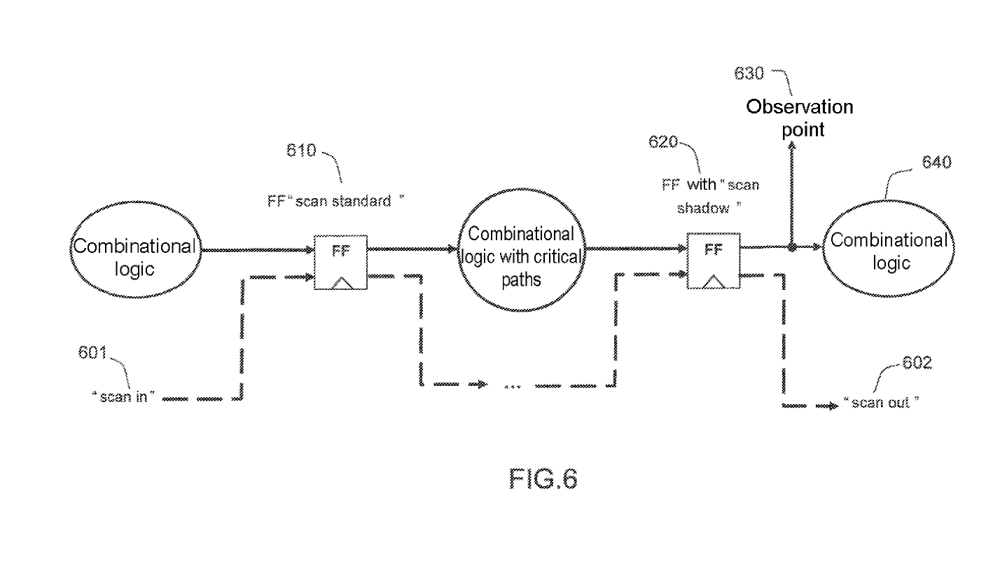

FIG. 6, an example of a scan chain architecture that comprises devices according to the FIGS. 1A and 2,

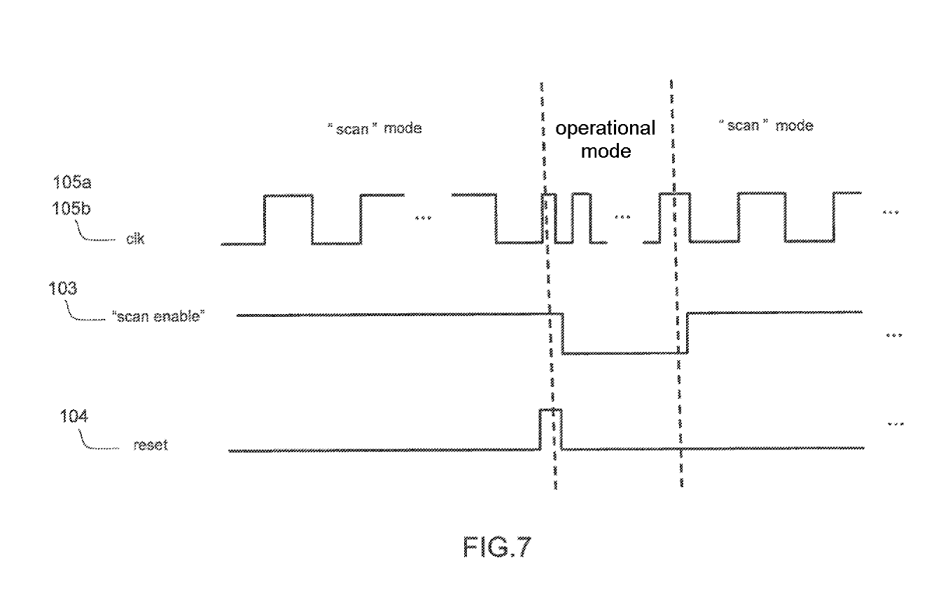

FIG. 7, a timing diagram with three useful signals for the monitoring of the test phase of a circuit containing scan chains according to FIG. 6,

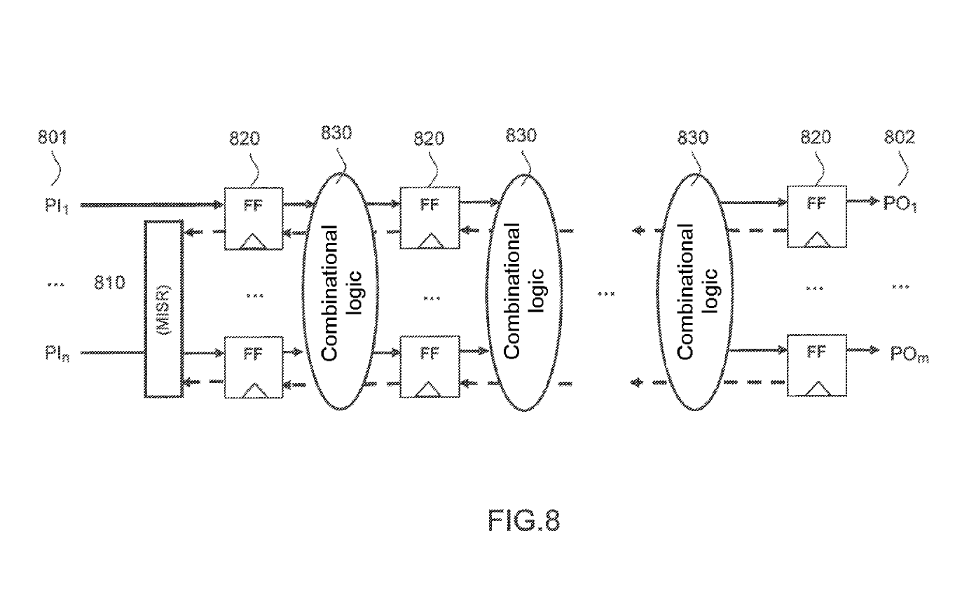

FIG. 8, a scan chain architecture for pipelined circuits based on the devices of FIG. 2,

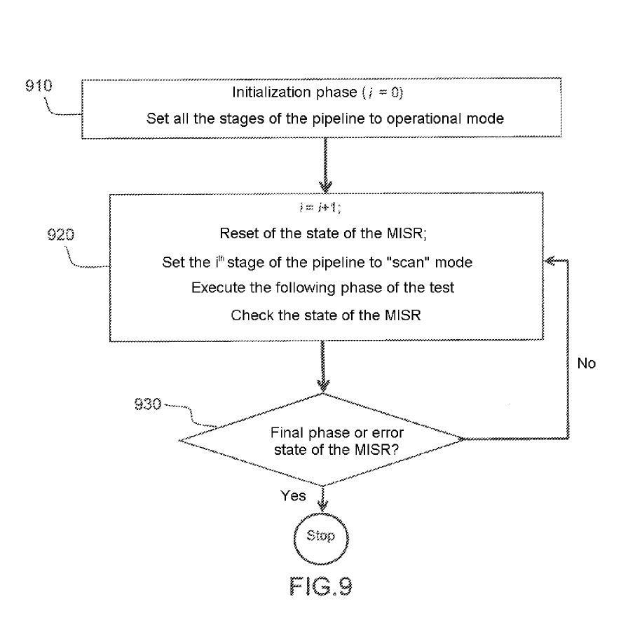

FIG. 9, a testing method implemented in architectures according to FIG. 8.

In the remainder of the description, it is considered by way of illustrative example that the state of the sampling elements is updated on the rising edge of the clock signal, which arrives at these sampling elements. For the sampling elements that have an explicit input making it possible to impose the holding of their state, the value logic 1 taken by the signal that controls their “hold” indicates the holding of the state of these sampling elements. For the sampling elements that have explicit inputs allowing their reset to zero, this operation is controlled by a signal called “reset” and triggered when this signal takes the value logic 1. For the sampling elements that can be controlled by signals of “hold” and “reset” type, it is considered that it is the “reset” signal that has priority. The “scan enable” signal is used to define two operating modes: a scan mode when the “scan enable” signal takes the value logic 1 and an operational or normal mode when the “scan enable” signal takes the value logic 0.

FIG. 1A is an example of a testing and monitoring device connected to a flip-flop 100. This device according to the invention can be inserted into scan chains and can be used for the on-line detection of timing faults affecting the signal “D” 101 based on time-shifted double sampling. The signal “D” 101 can be double-sampled by the standard flip-flop 100, which is a primary sampling element, and by the flip-flop 110, which is a secondary sampling, after having traveled through a “scan logic” module 120.

The signal D is transmitted directly to the first sampling element without passing through a multiplexer, or any other type of logic scan module, as represented in FIGS. 1A, 1B and 2.

The flip-flop 100, connected to the testing and monitoring device according to the invention, comprises an explicit input 111 which makes it possible to manage the state of the flip-flop, and notably to impose the holding of its state. To do this, a “hold logic” module 160 generates the signal enabling the holding of the state of the flip-flop 100 in scan mode. The flip-flop 100 also receives a first clock signal 105a which times the capture of the signal “D” 101.

The device also comprises a “scan logic” module 120 whose first input 120₁ receives the signal “D” and whose second input 120₂ receives the scan input or “scan in” signal. A third input 120₃ receives a “scan enable” signal 103. This “scan logic” module 120 with the signal 103 make it possible to choose the signal applied to the input of the flip-flop 100. The “scan in” signal is chosen to be in scan mode and the signal “D” 101 is chosen to be in operational mode. The scan input or “scan in” and scan output or “scan out” signals represent the connections downstream and upstream of the device according to the invention proposed in a scan chain. Two possible exemplary implementations of the “scan logic” module 120 are given in FIGS. 3A and 3B. The scan logic module is suitable for enabling the insertion of the secondary sampling element into a scan chain.

The output 120s of the “scan logic” module 120 is linked to the flip-flop 110. The flip-flop 110 is thus positioned after the “scan logic” module 120, or downstream, i.e. the signal D will first travel through the scan logic module before it is sampled by the flip-flop 110. The flip-flop 110 receives the output signal 109 of the scan logic module 160 and generates a “scan out” signal 106 at the flip-flop output. This flip-flop 110 can be implemented in such a way that it is less fast but also smaller than the flip-flop 100. The flip-flop 110 receives a second clock signal, 105b, for example the same as that received by the flip-flop 100. The two values D₁, D₂ of the signal “D”, captured by the flip-flop 100 and the flip-flop 110, are compared, in this exemplary implementation, by means of an XOR gate, 150, the result of which can be seen as an error signal or an alert 107. Without departing from the scope of the invention, it is possible to use the device without the gate 150.

In a variant embodiment, the primary sampling element 100 is suitable for updating its state on the falling edge of the clock signal 105a. In another variant, the primary sampling element 100 is suitable for updating its state on the high or low level of the clock signal 105a.

In a variant embodiment, the secondary sampling element 110 is suitable for updating its state on the falling edge of the clock signal 105b. In another variant, the secondary sampling element 110 is suitable for updating its state on the high or low level of the clock signal 105b.

The “hold logic” module 160 is adapted for generating the signal that enables the holding of the state of the flip-flop 100 in scan mode. This holding is, for example, imposed selectively using a “hold” signal 109 combined with the “scan enable” signal 103, and potentially, with the “Q” signal 108 corresponding to the output of the flip-flop 100. Possible exemplary implementations of the module “160” are given in FIG. 4. The presence of the “hold logic” module 160 is optional. In the absence of this module, the “hold” signal 109 is connected directly to the input 111 of the flip-flop 100. The “hold” signal can itself be optional.

Two NAND (inverted logic AND) gates, 130 and 140, ensure the generation of a reset-to-zero signal, 112, for the flip-flop 100. It is considered that the flip-flop 100 is reset to zero when the signal 112 takes the value logic 0. In operational or functional mode, the signal 112 is controlled by the “reset” signal 104 only, because the “scan enable” signal 103 takes the logic 0 value. In scan mode, characterized by the value logic 1 of the “scan enable” signal 103, the flip-flop 100 can be reset to zero selectively using the “scan in” 102 and “reset” 104 signals. The signal 112 can be forced to take the value logic 1, which prevents the flip-flop 100 from being reset, if the “scan in” signal 102 takes the value logic 1. The signal 112 takes the value logic 0 and the flip-flop 100 is reset if the “scan in” signal 102 takes the value logic 0 and the “reset” signal 104 takes the value logic 1. The gates 130 and 140 are optional and in their absence the “reset” signal 104 must be inverted and connected directly to the input 112 of the flip-flop 100. In the case where the flip-flop 100 does not have a “reset” input 112, the gates 130 and 140 and the “reset” signal 104 are not necessary. Other combinations of logic gates or implementations optimized at the transistor level can be implemented by those skilled in the art in order to obtain the same control of the signal 112.

FIG. 1B is a diagram of a variant for which the device according to the invention does not comprise any “hold logic” module 160. The “hold” signal 109 is optional and in the case where it exists it is applied to an input 111 of a primary sampling element 100′.

The NAND gate 140 receives the “reset” signal 104 on a first input. A second input 113 is driven by the output signal, “scan out” 106, of the secondary sampling element 110, the “scan out” signal being inverted by way of an inverter 170. The primary sampling element 100′ is chosen in such a way that its state is forced to the value logic 1 as soon as the “scan enable” signal 103 takes the value logic 1. For example, the primary sampling element 100′ can be implemented using a flip-flop with an input of “set” type which is driven by the “scan enable” signal 103. The other elements remain identical to those described in FIG. 1A.

FIG. 2 is a diagram of a variant embodiment of the device illustrated in FIG. 1A for flip-flops 200 that do not have an explicit input making it possible to impose the holding of their state. In this figure the elements identical to those described in FIG. 1A bear the same references.

In this variant embodiment, the holding of the state of these flip-flops is obtained by masking the clock signal, “clk” 105a, for example using a “hold logic” module 260.

In scan mode, the holding of the state of the flip-flops is selective because the “hold logic” module 260 is controlled, apart from the clock signal “clk” 105a, by the “scan enable” signal 103 and potentially by the signal “Q” 108, and the signal corresponds to the signal “D” after passing through the flip-flop 200. The “reset” signal 104 at the input of the “hold logic” module 260 is necessary only if the flip-flop 200 has a synchronous reset input. Possible implementations for the module 260 are described in FIG. 5.

An inverter 270 is arranged on the path of the clock signal “clk” 105b and in front of the flip-flop 110. In the case where the two clock signals 105a and 105b are identical, this inverter advantageously makes it possible to guarantee that the primary sampling element, or flip-flop 200, and the secondary sampling element 110 update their state on one and the same event (edge or level) of the clock signal and to balance the path traveled by the clock signal “clk” 105a all the way to the primary sampling element 200 and the path traveled by the clock signal “clk” 105b all the way to the secondary sampling element 110. It is also possible not to use the inverter 270; in this case, the clock signal 105b is linked directly to the flip-flop 110.

In both of the devices described in the figures, the “scan logic” module 120 introduces a difference in latency between the paths traveled by the two versions D₁, D₂ of the signal “D” before arriving at the primary and secondary sampling elements. This latency difference is used as a detection window for timing faults. In order to adjust the detection window introduced by this latency, it is possible to insert a timing element, such as a “buffer”, on the paths of the clock signals “clk”, 105a and 105b, arriving at the primary 100, 100′ and 200, or secondary 110 sampling elements respectively.

Without departing from the scope of the present invention, both the examples of devices described in FIGS. 1A and 2 can be implemented using other combinations of logic gates or implementations optimized at the transistor level.

The devices described in FIGS. 1A, 1B and 2 also allow the on-line detection of transient faults. In the case where this type of fault must be taken into account, the signal 107 at the output of the gate 150 is considered as an error signal. In the opposite case, the signal 107 can be considered as an alert signal indicating a risk of error only.

In order to reduce the power consumed by the devices described in FIGS. 1A, 1B and 2, the secondary sampling element 110, the “scan logic” element 120 and the element 150 can be disconnected from the power supply during operational modes in which there is no need to carry out testing or monitoring operations.

FIG. 3A presents a first mode of implementation for the “scan logic” module 120. This implementation is composed of a multiplexer 320 controlled by the “scan enable” signal 103, the multiplexer receiving the signal “D” 101 and the “scan in” signal 102.

FIG. 3B represents a second diagram of implementation, which comprises an XNOR gate (inverted exclusive logic OR) 322, a NOR (inverted logic OR) gate 323 and a NAND (inverted logic AND) gate 321. The “scan enable” 103 and activation of the debugging mode or “debug enable” 311 signals arriving at these gates must be inverted. The gate 322 can be replaced by an XOR (exclusive logic OR) gate not represented for simplification purposes, on the condition that the use of the signal 109 is appropriately modified. The “debug enable” signal 311 can be replaced by the “scan enable” signal 103. Moreover, the gate 321 is optional and, in its absence, the signal “D” 101 can be directly linked to the input of the XNOR gate 322. Other combinations of logic gates or optimizations at the transistor level can be used by those skilled in the art, without departing from the scope of the invention, with the reservation that they present the same functionality as that of the devices in FIGS. 3A and 3B.

The assembly formed by the secondary sampling element 110 in FIGS. 1A, 1B and 2 and the “scan logic” element 120 as it is implemented in FIG. 3A form the equivalent of a standard type of scan flip-flop, a “multiplexed data flip-flop”, according to the terminology used in the publication by M. Abramovici, M. A. Breuer, A. D. Friedman “Digital Systems Testing and Testable Design”, IEEE Press, 1990, pages 369-370. This assembly can be replaced by another type of standard scan flip-flop such as, for example, the “level-sensitive scan design” (LSSD) scan architecture, the “two-port dual-clock flip-flop”, or the “multiplex data shift register latch” described in the same publication, pages 370-372. Modifications easily identified by those skilled in the art make it possible to use other types of standard scan flip-flop, such as those mentioned above for example, in place of the “multiplexed data flip-flop”.

FIGS. 4A and 4B represent two possible exemplary implementations of the “hold logic” module 160 for primary sampling elements 100 which have an explicit input making it possible to impose the holding of their state.

The first implementation in FIG. 4A is composed of a NAND (inverted logic AND) gate 460 whose inputs “scan enable” 103 and “hold” 109, defined in FIG. 1, must be inverted. In this implementation, the state of the flip-flop 100 is held if one of the two signals, “hold” 109 or “scan enable” 103, takes the value logic 1.

The second implementation in FIG. 4B allows a selective hold in scan mode using the additional help of the signal “Q” 108 at the input. This implementation requires two NAND (inverted logic AND) gates 461 and 462 whose input corresponding to the “hold” signal 109 must be inverted. In this implementation, the state of the flip-flop 100 is held: if (i) the “hold” signal 109 takes the value logic 1 or ii) if the “Q” 108 and “scan enable” 103 signals take the value logic 1.

Other combinations of logic gates or implementations optimized at the transistor level can be implemented by those skilled in the art in order to obtain the same functionality as that supplied by the devices in FIGS. 4A and 4B.

The FIGS. 5A, 5B and 5C present three possible implementations of the “hold logic” module 260 for primary sampling elements 200 (FIG. 2) that have no explicit input making it possible for the holding of their state to be imposed. In the first two implementations, FIGS. 5A and 5B, the state of the flip-flop 200 is held by blocking the clock signal 213 at the value logic 0, while in the third implementation, FIG. 5C, the clock signal 213 is blocked at the value logic 1. The implementations of the FIGS. 5B and 5C allow a selective hold in scan mode using the additional help of the signal “Q” 108 at input.

The first implementation, in FIG. 5A, is composed of a NOR (inverted logic OR) gate 560 and an AND (logic AND) gate 561. The gate 560 receives the clock signal 105a as input and a signal corresponding to the output of the gate 561. In this implementation, the state of the flip-flop 200 is held if the “scan enable” signal 103 takes the value logic 1 and the “reset” signal 104 takes the value logic 0.

The second implementation, in FIG. 5B, is composed of a NOR (inverted logic OR) gate 562 and an AND (logic AND) gate 563. The gate 562 receives the clock signal 105a on a first input and the output of the gate 563 on a second input. In this implementation, the state of the flip-flop 200 is held if the “scan enable” 103 and “Q” 108 signals take the value logic 1 and the “reset” signal takes the value logic 0.

In its third implementation, in FIG. 5C, the “hold logic” module contains two NAND (inverted logic AND) gates 564 and 565, and the output of the gate 565 corresponds to an input of the gate 564. The holding of the state of the flip-flop 200 is ensured by the same conditions necessary for the holding in the case of the implementation in FIG. 5B. The only difference is that in the case of the implementation in FIG. 5B it is necessary to consider as an additional constraint the fact that the output of the gate 565 must not undergo a transition from logic 1 to logic 0 while the clock signal “clk” 105a is at the logic 1 value.

In the devices in FIG. 5A, FIG. 5B and FIG. 5C, the use of the “reset” signal is necessary only if the flip-flop 200 has a “reset” input synchronous with the clock signal “clk” 105a. In this case, the gates 563 and 565 have only two inputs corresponding to the “Q” 108 and “scan enable” 103 signals while the gate 561 is no longer necessary, the “scan enable” signal 103 being directly connected to the gate 560. The elimination of the “reset” signal 104 is equivalent to the blocking at the value logic 0 of the input, which receives this signal in the gates 561, 563 and 565. Other combinations of logic gates or implementations optimized at the transistor level can be used by those skilled in the art in order to obtain the same functionality as that supplied by the devices in FIGS. 5A, 5B and 5C.

FIG. 6 presents an example of a scan chain architecture called “mixed-scan” that can contain standard scan flip-flops 610 and testing and monitoring devices, similar to the devices presented in FIGS. 1A, 1B and 2, connected to flip-flops 620. Unlike the proposed testing and monitoring devices, the standard scan flip-flops 610 are employed both to perform the computations relating to the functionality of a circuit and to facilitate the testing of this circuit. Without the testing and monitoring devices, the flip-flops 620 can be used only to carry out the computations relating to the functionality of a circuit.

In the circuit where such a scan chain is inserted, it is considered that at least some of the flip-flops that are found on critical paths are protected by devices similar to those presented, for example, in FIGS. 1A, 1B and 2. In this case, these devices are included in one or more scan chains while the primary sampling elements are not included in the scan chains so as not to affect the latency of the circuit. The outputs of the flip-flops 620 that are not in scan chains can be observed using observation points 630 known to those skilled in the art in the field of design for testing. These observation points can be inserted in turn into scan chains or into MISRs (Multiple-Input Signature Registers) known to those skilled in the art.

FIG. 7 is a diagram of an example for the shape of the signals used in the course of a production test method comprising a series of scan and operational modes. In this example three signals enable the control of the testing of a circuit comprising a configuration of scan chains similar to that illustrated in FIG. 6.

The “reset” signal 104 takes the value logic 1 during the last clock cycle executed in scan mode, defined by the value logic 1 of the “scan enable” signal 103, in order to selectively reset the primary sampling elements which are not comprised in the scan chains and which have a testing and monitoring device as introduced in this patent. In scan mode, this “reset” signal 104 must not affect the standard scan flip-flops. In operational mode, it is enough to apply one or more cycles at the closest possible frequency to the target frequency of the circuit.

This example corresponds to the situation where the two clock signals 105a and 105b are identical and the assembly formed by the elements 110 and 120 (as implemented in FIG. 3A, for example) is equivalent to the type of standard scan flip-flop called “multiplexed data flip-flop” and mentioned beforehand.

According to another embodiment, the “reset” signal 104 takes the value logic 1 during the first clock cycle executed in operational mode defined by the value logic 0 of the “scan enable” signal 103, and it returns to the value logic 0 before the first rising edge of the clock signal, still in operational mode. This makes it possible to selectively reset the primary sampling elements which are not comprised in the scan chains and which have a testing and monitoring device according to the invention.

Without departing from the scope of the invention, for the devices described in FIGS. 1A-5 and 7, those skilled in the art can easily implement the necessary modifications to the latter in the case where at least one of the following situations occurs:

(i) some or all of the sampling elements 100, 100′, 110 and 200 can update their state during the falling edge of the clock signal arriving at these sampling elements,
(ii) some or all of the sampling elements 100, 100′, 110 and 200 can update their state on the high or low level of the clock signal arriving at these sampling elements,
(iii) the value logic 1 of the signal 112 and value logic 0 of the “reset” signal 104 are used to reset the primary sampling elements 100 and 200,
(iv) the value logic 0 of the “hold” signal 109 and 111 is used to ensure the holding of the state of the primary sampling element 100,
(v) the values of the “scan enable” signal 103 used to signal the scan and operational modes are inverted.
(vi) the assembly formed by the elements 110 and 120 (FIGS. 1A, 1B and 2) is equivalent to another type of standards can flip-flop such as, for example, “level-sensitive scan design” (LSSD), “two-port dual-clock flip-flop”, “multiplex data shift register latch” mentioned beforehand.

FIG. 8 represents another example of scan chain architecture that can be used for “pipelined” circuits.

The elements 820 represent flip-flops protected by similar devices to those presented in FIG. 2 with a “scan logic” module as implemented in FIG. 3B. The protected flip-flops are not comprised in the scan chains and only these devices are comprised in scan chains. It is recommended that each scan chain contains a single device per stage of the pipelines. The information in the scan chains circulates in the opposite direction to the operational flow of information. Consequently, the last devices in the scan chains are part of the first stages of the pipeline. An MISR (Multi-Input Signature Register) can be used to compress the outputs of the scan chains by way of an on-line testing program. The state of the MISR must be accessible to the on-line testing program, i.e. it must be possible to read and at least to reset its state. Additionally, the MISR must be overridable during the production test (off-line) in order to allow better observability. The inputs 801 and the outputs 802 are operational inputs and outputs of the pipeline. In this architecture, the scan chains have no inputs coming from the outside.

FIG. 9 presents a diagram of the steps implemented in a method for partitioning a testing program into several steps in order to reduce the probability of error masking or “aliasing” in pipelined circuits containing devices similar to those represented in FIG. 8.

In agreement with this method, the testing program begins with an initialization step 910 with all the stages of the pipeline in operational mode. The initialization step is followed by a series of steps 920 at the start of which a stage of the pipeline is placed in observation and monitoring mode or in “scan mode”. The first stage to be placed in scan mode is the stage at the input of the pipeline (far left in FIG. 8), i.e. the stage that contains the last elements in the scan chains illustrated in FIG. 8. At each new step 920, the following stage that adjoins the last stage to have passed into scan mode is in turn passed into scan mode without changing the mode of the other stages; this presupposes the existence of a “scan enable” signal for each stage of the pipeline that is controllable by the testing program. For example, these “scan enable” signals can be generated from the state of a control register. The contents of the MISR illustrated in FIG. 8 can be reset at the start of each step 920. The cessation of the method is controlled using the step 930 executed after each step 920. The method is ceased if all the stages have been tested in scan mode or if, at the end of a step 920, the state of the MISR in FIG. 8 is incorrect. At the end, the testing program must indicate the success or lack of success of the test operation. For this type of test, the diagram presented in FIG. 7 does not apply.

The device according to the invention notably presents the advantage of avoiding the insertion of standard flip-flops into critical paths and the fact of minimizing the impact of design solutions with a view to testing.

1. A device for testing and monitoring digital circuits enabling the detection of timing faults affecting a signal D received directly at the input of a flip-flop called primary sampling element, said primary sampling element supplying a first value D₁ of the signal D and receiving a first clock signal for its updating, said testing and monitoring device comprising at least:
a scan logic module introducing a latency in the signal D, said scan logic module having a first input receiving the signal “D”, a second input receiving a “scan in” signal and a third input receiving a “scan enable” signal adapted for selecting the operating mode of the testing and monitoring device in a scan mode or an operational mode, and an output linked to a secondary sampling element of the signal “D” and supplying a second sampled signal D₂ of the signal D after passing through the scan logic module, said secondary sampling element receiving a second clock signal (105b) for updating its state, and
a module for comparison of the signal D₁ and the signal D₂ generating an alert or error signal.

2. The device as claimed in claim 1, further comprising a module supplying a “reset” signal to said primary sampling element.

3. The device as claimed in claim 2, wherein the module supplying a “reset” signal to the primary sampling element comprises a first NAND gate and a second NAND gate adapted to allow a selective “reset” in scan mode and a normal “reset” in operational mode.

4. The device as claimed in claim 2, wherein the module supplying a “reset” signal to the primary sampling element comprises a first NAND gate with a first input receiving a reset signal and a second input receiving the inverted output signal of the secondary sampling element “scan out” and in that the primary sampling element is chosen so that its state is forced to the value logic 1 as soon as the “scan enable” signal takes the value logic 1.

5. The device as claimed in claim 1, wherein further comprising a module adapted for generating a signal for controlling the holding of the state of said primary sampling element.

6. The device as claimed in claim 1, wherein the first clock signal and the second clock signal are identical.

7. The device as claimed in claim 1, wherein the assembly formed by said secondary sampling element and the “scan logic” module form a scan flip-flop.

8. The device as claimed in claim 1, further comprising an XOR gate used to compare the versions of the signal “D” sampled by said primary sampling element and by said secondary sampling element.

9. The device as claimed in claim 1, further comprising an inverter on the path of the second clock signal.

10. The device as claimed in claim 1, further comprising a timing element arranged on the path of the first clock signal arriving at the primary sampling element and/or a timing element arranged on the path of the second clock signal arriving at the secondary sampling element.

11. The device as claimed in claim 1, wherein the “scan logic” module comprises a multiplexer controlled by the “scan enable” signal.

12. The device as claimed in claim 1, wherein the “scan logic” module comprises an XNOR gate, a NOR gate and a NAND gate or an XOR gate, a NOR gate and a NAND gate.

13. The device as claimed in claim 5, wherein for a primary sampling element comprising an explicit input for a hold signal “hold”, the “hold logic” module is composed of a NAND gate who “scan enable” and “hold” inputs are inverted.

14. The device as claimed in claim 5, wherein for a primary sampling element comprising an explicit input for a hold signal “hold”, the “hold logic” module is composed of two NAND gates whose “hold” input is inverted.

15. The device as claimed in claim 5, wherein for a primary sampling element not including an explicit input for a hold signal “hold”, the “hold logic” module is composed of a NOR gate receiving the clock signal and the “scan enable” signal as input.

16. The device as claimed in claim 5 wherein for a primary sampling element not including an explicit input for a hold signal “hold”, the “hold logic” module is composed of a NOR gate and an AND gate the NOR gate receives the clock signal on a first input and the output of the AND gate on a second input.

17. The device as claimed in claim 5 wherein for a primary sampling element not including an explicit input for a hold signal “hold”, the “hold logic” module contains a first NAND gate and a second NAND gate, and the first NAND gate receives the first clock signal on a first input and the output of the second NAND gate on a second input.

18. The device as claimed in claim 15, further comprising an AND gate or a NAND gate and one of the inputs of said gates corresponding to the “reset” signal is blocked at the value logic 0.

19. The device as claimed in claim 1 wherein at least some of the primary and/or secondary sampling elements are suitable for updating their state on the falling edge of the clock signal.

20. The device as claimed in claim 5, wherein at least some of the primary and/or secondary sampling elements are adapted for updating their state on the high or low level of the clock signal.

21. The device as claimed in claim 16 comprising an AND gate or a NAND gate and one of the inputs of said gates corresponding to the “reset” signal is blocked at the value logic 0.

22. The device as claimed in claim 17 comprising an AND gate or a NAND gate and one of the inputs of said gates corresponding to the “reset” signal is blocked at the value logic 0.
